(19) United States
(12) Patent Application Publication
(10) Pub. No.: US 2024/0113102 A1
(43) Pub. Date: Apr. 4, 2024

(54) BURIED TRENCH CAPACITOR

(71) Applicant: Texas Instruments Incorporated, Dallas, TX (US)

(72) Inventors: Umamaheswari Aghoram, Richardson, TX (US); Guruvayurappan Mathur, Allen, TX (US); Robert Oppen, Phoenix, AZ (US); Tawen Mei, Sunnyvale, CA (US)

(21) Appl. No.: 17/957,931

(22) Filed: Sep. 30, 2022

(51) Int. Cl. H01L 27/06; H01L 29/66; H01L 29/94

(52) U.S. Cl. CPC H01L 27/0629; H01L 29/66181; H01L 29/945

(57) ABSTRACT

A microelectronic device includes a buried trench capacitor below an electronic component of the microelectronic device. In one embodiment, the buried trench capacitor may be formed between a silicon oxide capped p-type buried trench capacitor polysilicon region and a buried trench capacitor deep n-type region separated by buried trench capacitor liner dielectric. In a second embodiment, the buried trench capacitor may be formed by a buried trench capacitor polysilicon region and a p-type silicon epitaxial region separated by a buried trench capacitor liner dielectric. One terminal of the deep trench capacitor is made through the substrate via a deep trench substrate contact. The second terminal of the deep trench capacitor is made via a well contact that connects to the capacitor through a deep well region in one embodiment and through a polysilicon layer in a second embodiment.

### FIELD

This disclosure relates to the field of microelectronic devices. More particularly, but not exclusively, this disclosure relates to buried trench capacitors in microelectronic devices.

### BACKGROUND

Bypass capacitors have been used in conjunction with microelectronic devices such as switched mode power converters. In such devices, capacitor properties such as electromagnetic interference (EMI) are important to performance. EMI has previously been improved by moving the bypass capacitors from separate chips into the same chip as the microelectronic device. Further improvements in integrating capacitors into microelectronic devices are needed.

### SUMMARY

The present disclosure introduces a microelectronic device including a buried trench capacitor below the top surface of the microelectronic device. In one embodiment, the buried trench capacitor may be formed between a silicon oxide capped buried trench capacitor polysilicon region and a buried trench capacitor deep well region separated by a buried trench capacitor liner dielectric. In a second embodiment, the buried trench capacitor may be formed by a buried trench capacitor polysilicon region and a silicon epitaxial region separated by a buried trench liner dielectric. One terminal of the deep trench capacitor is made through the substrate via a deep trench substrate contact. The second terminal of the deep trench capacitor is made via a well contact that connects to the capacitor through a deep well region in one embodiment and through a polysilicon layer in a second embodiment.

### BRIEF DESCRIPTION OF THE VIEWS OF THE DRAWINGS

FIG. 1A through FIG. 1K are cross sections of a first embodiment of an example microelectronic device with a buried trench capacitor depicted in successive stages of an example method of formation.

FIG. 2A through FIG. 2I are cross sections of a second embodiment of an example microelectronic device with a buried trench capacitor depicted in successive stages of an example method of formation.

FIG. 3 is a top down view of another microelectronic device with a buried trench capacitor.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two-dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

It is noted that terms such as top, bottom, front, back, over, above, under, and below may be used in this disclosure. These terms should not be construed as limiting the position or orientation of a structure or element, but should be used to provide spatial relationship between structures or elements. Similarly, words such as “inward” and “outward” would refer to directions toward and away from, respectively, the geometric center of a device or area and designated parts thereof.

For the purposes of this disclosure, the term “lateral” refers to a direction parallel to a plane of the instant top surface of the microelectronic device the term “vertical” is understood to refer to a direction perpendicular to the plane of the instant top surface of the microelectronic device.

For the purposes of this disclosure, the term “conductive” is to be interpreted as “electrically conductive”. The term “conductive” refers to materials and structures capable of supporting a steady electrical current, that is, direct current (DC).

A microelectronic device is formed in and on a substrate having a semiconductor material. The microelectronic device includes a buried capacitor cell below a top surface of the semiconductor material. The buried capacitor cell includes a trench liner dielectric layer in each buried capacitor cell. The buried capacitor cell further includes an electrically conductive trench-fill material on the trench liner dielectric layer in each buried capacitor cell.

The microelectronic device may have a deep trench adjacent to an array of buried capacitor cells which provides a contact to the substrate. For the purposes of the disclosure, the term deep trench is a trench deeper in the semiconductor material than a field oxide.

An electrical component is above the buried trench capacitor array of the integrated buried capacitor. In one example, the electrical component is a transistor such as aa laterally diffused MOS transistor (LDMOS) transistor, a drain extended metal oxide semiconductor (DEMOS) transistor, a bipolar junction transistor, a junction field effect transistor, a gated bipolar, a gated unipolar semiconductor device, or an insulated gate bipolar transistor (IGBT). In other examples, the electronic component is a silicon controlled rectifier (SCR), a metal oxide semiconductor (MOS)-triggered SCR, a MOS-controlled thyristor, a gated diode, an amplifier, or a Schottky diode by way of example. Placement of a buried capacitor in the microelectronic device below or near the electrical component of the microelectronic devices is advantageous as physically locating the buried trench capacitor array below or near the electrical component may lower the electromagnetic interference (EMI) of the microelectronic device. Additionally, physically locating the buried trench capacitor array below the electrical component or at least partially below the electrical component provides a silicon area savings.

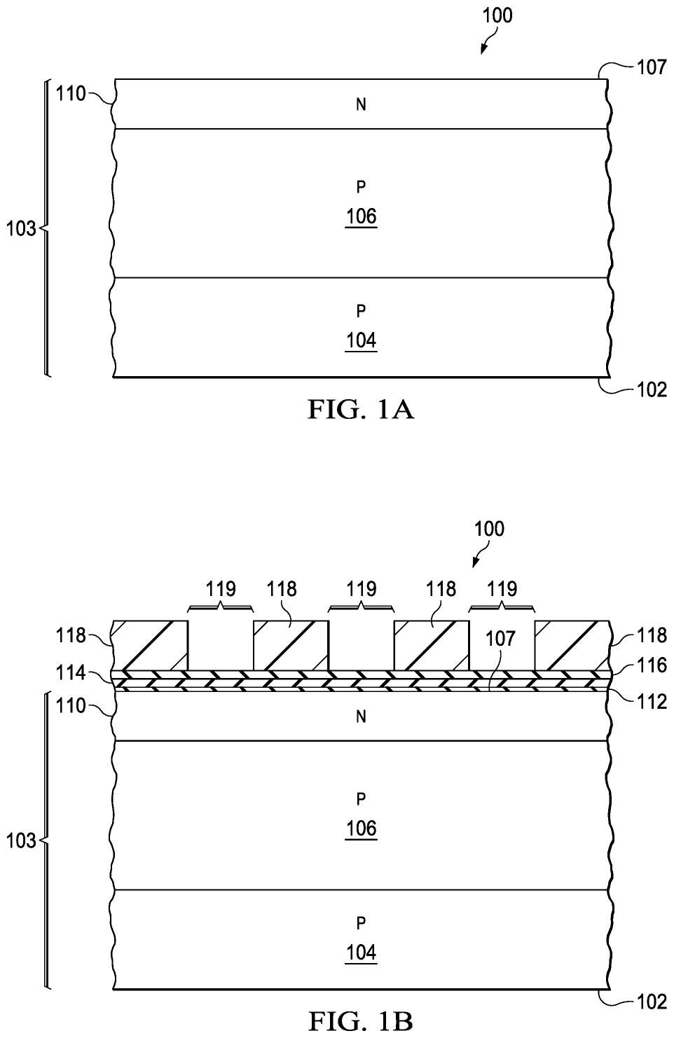

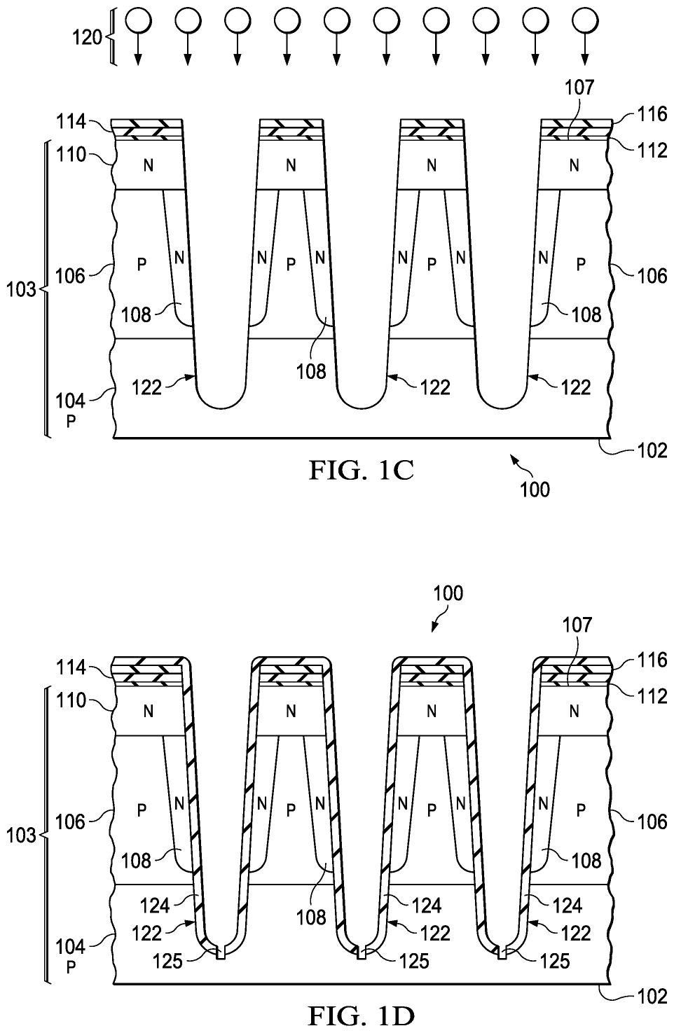

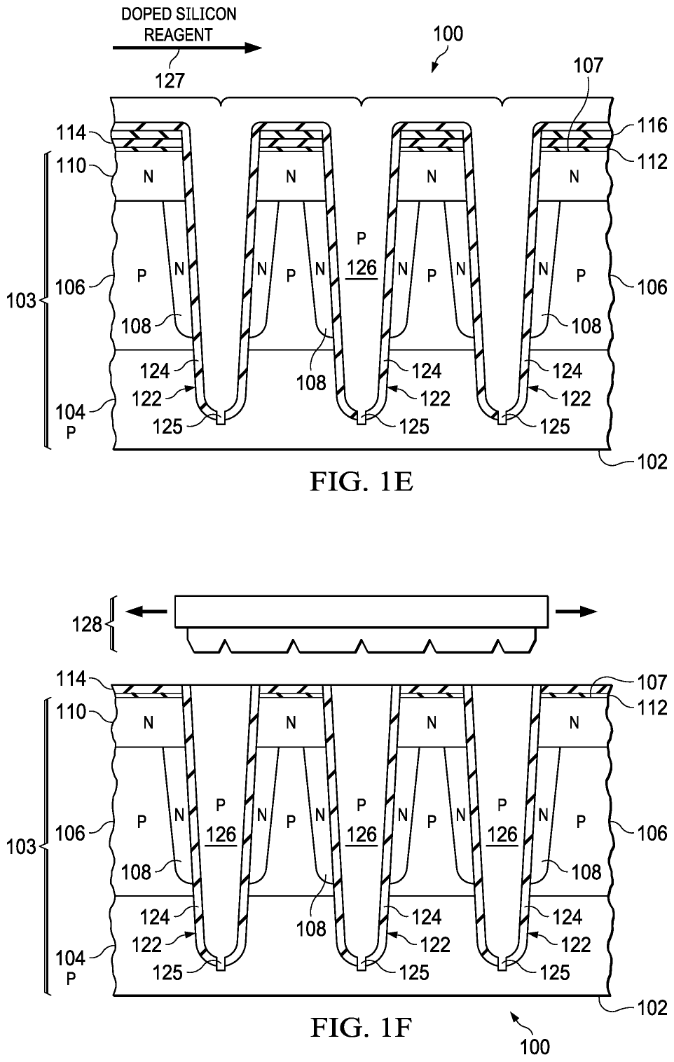

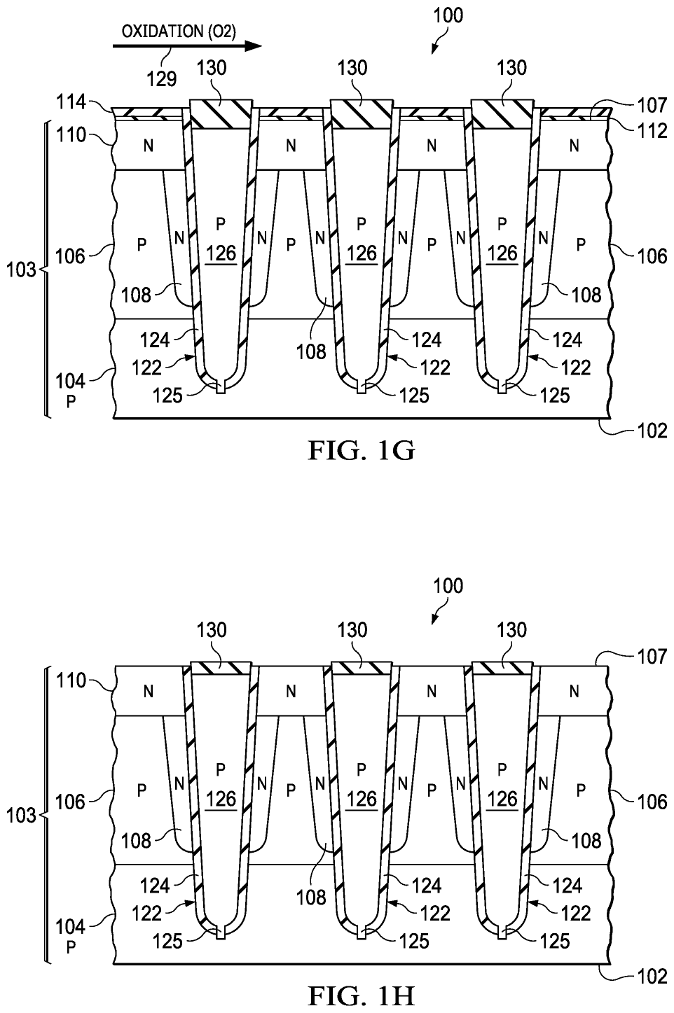

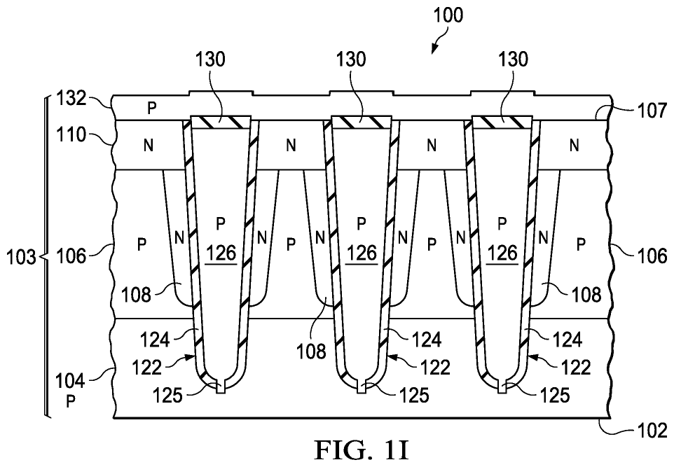

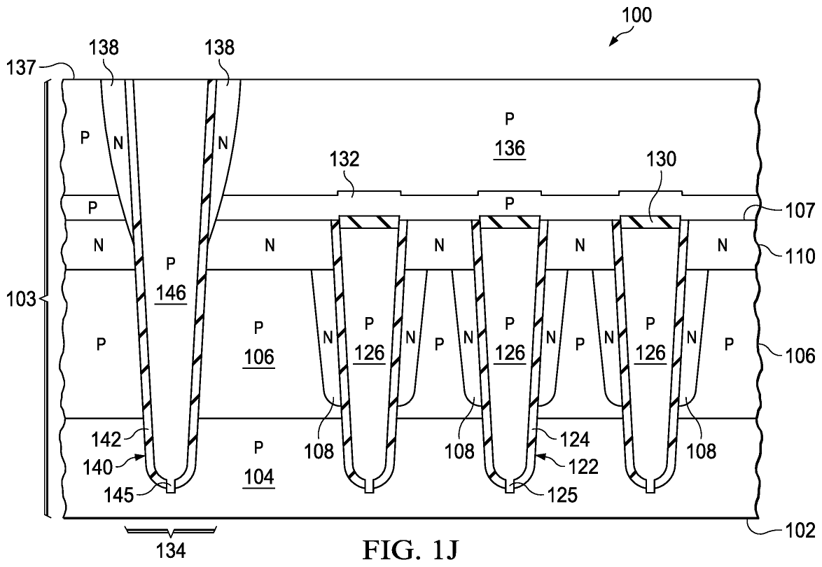

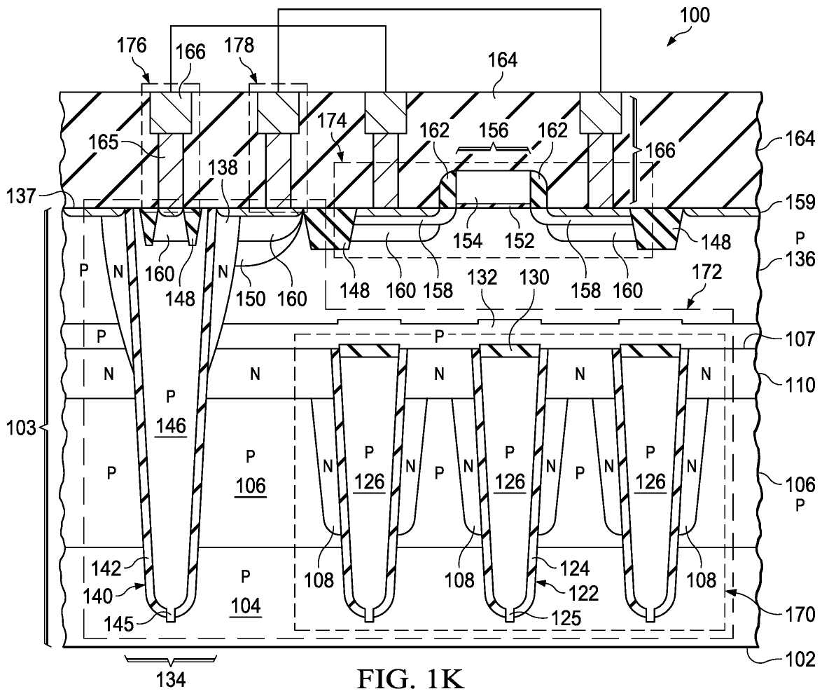

FIG. 1A through FIG. 1K are cross sections of an example microelectronic device 100 depicted in successive stages of an example method of formation containing a buried trench capacitor array 170 as part of an integrated buried capacitor 172, the integrated buried capacitor 172 providing a capacitance source to an electrical component 174.

Referring to FIG. 1A, the microelectronic device 100 includes a substrate 102 that has a semiconductor material 103 referred to herein as the silicon 103. In an alternate version of this example, the substrate 102 may include a dielectric material, such as silicon dioxide or sapphire, to provide a silicon-on-insulator substrate. In this example, the substrate 102 may include a base wafer 104, such as a silicon wafer. The base wafer 104 may have a first conductivity type, which is shown as p-type in this example. A first epitaxial layer 106 which is doped is formed on the base wafer 104. The first epitaxial layer 106 includes primarily silicon, and may consist essentially of silicon and dopants, such as boron. The first epitaxial layer 106 has a first epitaxial top surface 107. In this example, the first epitaxial layer 106 may have the first conductivity type, that is, p-type. The first epitaxial layer 106 may be 5 microns to 15 microns thick, by way of example.

A buried layer 110 may be formed in the first epitaxial layer 106. The buried layer 110 has a second conductivity type, opposite from the first conductivity type. In this example, the second conductivity type is n-type. The buried layer 110 may be formed by implanting dopants of the second conductivity type, such as phosphorus, arsenic, or antimony, into first epitaxial layer 106. The buried layer 110 may have an average dopant density greater than twice an average dopant density of the first epitaxial layer 106. The base wafer 104 may be annealed after the buried layer implant.

Referring to FIG. 1B, a pad oxide layer 112 may be formed on the first epitaxial top surface 107 of the first epitaxial layer 106. The pad oxide layer 112 may include primarily silicon dioxide, may be formed by a thermal oxidation process or a thermal chemical vapor deposition (CVD) process, and may have a thickness of 50 nanometers to 200 nanometers, by way of example. A nitride cap layer 114 may be formed on the pad oxide layer 112. The nitride cap layer 114 may include primarily silicon nitride, may be formed by a low-pressure chemical vapor deposition (LPCVD) furnace process, and may have a thickness of 100 nanometers to 500 nanometers, for example. A hard mask layer 116 may be formed on the nitride cap layer 114. The hard mask layer 116 may include primarily silicon dioxide, may be formed by a plasma enhanced chemical vapor deposition (PECVD) process, and may have a thickness of 1 micron to 3 microns, depending on a depth of subsequently-formed buried capacitor trench 122, shown in FIG. 1C. The pad oxide layer 112 may provide stress relief between the first epitaxial layer 106 and a combination of the nitride cap layer 114 and the hard mask layer 116. The nitride cap layer 114 may provide a stop layer for subsequent etch and planarization processes. The hard mask layer 116 may provide a hard mask during a subsequent buried capacitor etch process 120 discussed in FIG. 1C to form the buried capacitor trench 122. Next, a buried capacitor trench mask 118 may be formed on the hard mask layer 116 with buried capacitor trench mask openings 119 which expose the hard mask layer 116 in an area for the buried capacitor trench 122. The buried capacitor trench mask 118 may include photoresist, and may optionally include anti-reflection material such as a bottom anti-reflection coat (BARC). The buried capacitor trench mask 118 may be formed by a photolithographic process.

Referring to FIG. 1C, a buried capacitor etch process 120 is performed to form the buried capacitor trench 122 in the first epitaxial layer 106. A buried capacitor trench 122 is formed for each desired capacitor cell, the capacitor cells forming an array of capacitor cells. The buried capacitor etch process 120 may include multiple steps. In one implementation, a hard mask etch may be first performed to remove the hard mask layer 116 where exposed by the buried capacitor trench mask 118 of FIG. 1B, and a silicon etch may then be performed to remove the nitride cap layer 114, the pad oxide layer 112, and the first epitaxial layer 106 in regions that are exposed by the hard mask layer 116 to form the buried capacitor trench 122. The buried capacitor trench 122 extends from the first epitaxial top surface 107 into the first epitaxial layer 106 and may extend into the base wafer 204. During the silicon etch, the buried capacitor trench mask 118 may also be partially or completely removed, leaving the hard mask layer 116 to prevent the area outside of the buried capacitor trench 122 from being etched. FIG. 1C depicts the buried capacitor etch process 120 at completion, and the buried capacitor trench mask 118 has been removed by the subsequent buried capacitor trench etch clean-up process (not specifically shown). The organic polymers in the buried capacitor trench mask 118 may be removed using an oxygen plasma, followed by a series of wet etch processes, including an aqueous mixture of sulfuric acid and hydrogen peroxide, an aqueous mixture of ammonium hydroxide and hydrogen peroxide, and an aqueous mixture of hydrochloric acid and hydrogen peroxide.

A buried capacitor deep well 108 may be formed in the first epitaxial layer 106, extending past the bottom edge of the buried layer 110 along edges of the buried capacitor trench 122. The buried capacitor deep well 108 may be formed by implanting dopants of the second conductivity type, such as phosphorus, using an angled implant to implant the dopants along edges of the buried capacitor trench 122 beyond the buried layer 110 into the first epitaxial layer 106, followed by a thermal drive to diffuse and activate the implanted dopants. The buried capacitor deep well 108 may have an average concentration of the dopants of the second conductivity type that is 2 to 10 times greater than an average concentration of dopants of the first conductivity type in the first epitaxial layer 106 outside of the buried capacitor deep well 108. An angled implant may provide improved implant distributions by implanting through the buried capacitor trench 122 walls.

Referring to FIG. 1D, a buried capacitor trench liner dielectric layer 124 herein referred to as a trench liner dielectric layer 124 is formed in the buried capacitor trench 122, contacting the first epitaxial layer 106 and the base wafer 104 as well as the buried capacitor deep well 108 and buried layer 110. The trench liner dielectric layer 124 may extend over the hard mask layer 116, the nitride cap layer 114, and the pad oxide layer 112. The trench liner dielectric layer 124 may include a single layer of a silicon-nitrogen compound or a silicon dioxide compound or may include multiple layers of silicon-nitrogen compounds, silicon dioxide compounds, or other dielectric materials. After the formation of the trench liner dielectric layer 124, a trench liner dielectric layer etch process (not specifically shown) is used to form a trench liner gap 125 through the bottom of trench liner dielectric layer 124 exposing the base wafer 104.

Referring to FIG. 1E, a trench-fill material 126 is formed in the buried capacitor trench 122 on the trench liner dielectric layer 124. The trench-fill material 126 is electrically conductive. The trench-fill material 126 includes primarily silicon, and may be implemented as polycrystalline silicon, commonly referred to as polysilicon. Alternatively, the trench-fill material 126 may be implemented as amorphous silicon, or semi-amorphous silicon. The trench-fill material 126 may have the first conductivity type, p-type in this example. The trench-fill material 126 may have an average concentration of dopants of 5×10¹⁸ cm⁻³ and 1×10²⁰ cm⁻³, to provide a low equivalent resistance for the buried trench capacitor array 170. The trench-fill material 126 may be formed by thermal decomposition of a silicon-containing reagent gas that includes a doped polysilicon reagent 127. The trench-fill material 126 fills the buried capacitor trench 122 and may extend outside of the buried capacitor trench 122.

Referring to FIG. 1F, the trench-fill material 126 and the trench liner dielectric layer 124 are removed from outside of the buried capacitor trench 122. The trench-fill material 126 and the trench liner dielectric layer 124 may be removed by a planarization process, such as a chemical mechanical polish (CMP) process 128, as indicated in FIG. 1F. Alternatively, the trench-fill material 126 and the trench liner dielectric layer 124 may be removed by an etch back process. The process of removing the trench-fill material 126 and the trench liner dielectric layer 124 outside of the buried capacitor trench 122 leaves the trench-fill material 126 on the trench liner dielectric layer 124 in the buried capacitor trench 122. The process of removing the trench-fill material 126 and the trench liner dielectric layer 124 may leave the nitride cap layer 114 and the pad oxide layer 112 on the first epitaxial top surface 107 of the first epitaxial layer 106. The nitride cap layer 114 may provide a selective template layer for the subsequent polysilicon oxidation process 129 shown in FIG. 1G.

Referring to FIG. 1G, a polysilicon oxidation process 129 is used to form a buried capacitor silicon dioxide cap 130 which provides a dielectric barrier over the trench-fill material 126 of the buried trench capacitor array 170. The polysilicon oxidation process 129 may use oxygen or oxygen and steam at high temperature to oxidize the trench-fill material 126 at the first epitaxial top surface 107 of the first epitaxial layer 106. The nitride cap layer 114 prevents oxidation in regions other than the trench fill material 126.

Referring to FIG. 1H, The nitride cap layer 114 and the pad oxide layer 112 are removed. The nitride cap layer 114 may be removed by a wet etch process using an aqueous solution of phosphoric acid at 140° C. to 170° C. The pad oxide layer 112 may be removed by a wet etch process using an aqueous solution of buffered hydrofluoric acid. The pad oxide layer 112 removal process is optimized to remove the pad oxide layer 112, but not to remove excess buried capacitor silicon dioxide cap 130 to the point that it would affect the dielectric integrity of the buried capacitor silicon dioxide cap 130. After the removal of the pad ox layer 112, the buried capacitor silicon dioxide cap 130 is continuous over the trench-fill material 126.

Referring to FIG. 1I, an epitaxial silicon capping layer 132 is deposited over the buried capacitor silicon dioxide cap 130. The epitaxial silicon capping layer 132 has the first conductivity type, p-type in this example. The epitaxial silicon capping layer 132 may be 1 micron to 3 microns by way of example. The epitaxial silicon capping layer 132 may contain p-type dopants such as boron at a concentration of 1×10¹⁵ atoms/cm³ to 1×10¹⁶ atoms/cm³

Referring to FIG. 1J, a top epitaxial silicon 136 layer with first conductivity type (e.g., p-type) doping and an integrated deep trench 134 are formed. After the deposition of the epitaxial silicon capping layer 132, the top epitaxial silicon 136 layer is deposited. The top epitaxial silicon 136 layer has a top epitaxial silicon top surface 137. The top epitaxial silicon 136 layer may contain p-type dopants such as boron at a concentration of 1×10¹⁵ atoms/cm³ to 1×10¹⁶ atoms/cm³, by way of example. The thickness of the top epitaxial silicon 136 layer may be between 5 and 15 microns by way of example. After the formation of the top epitaxial silicon 136 layer, a pattern and implant step are used to form a deep trench deep well region 138. The deep trench deep well region 138 has the second conductivity type (e.g., n-type). Alternatively, the deep trench deep well region 138 may be formed after the formation of the integrated deep trench 134.

The integrated deep trench 134 makes an electrical connection from the top epitaxial silicon top surface 137 of the microelectronic device 100 to the base wafer 104. The formation of the integrated deep trench 134 consists of an integrated deep trench hard mask layer formation step, a photolithographic pattern step, a plasma etch step, and a clean-up step (none specifically shown) which form the integrated deep trench 134.

After the formation of the deep trench 140, a deep trench liner 142 is deposited. The deep trench liner 142 is a dielectric layer. The deep trench liner 142 may be 50 A to 300 A by way of example. The deep trench liner 142 may be a single layer or multiple layers of dielectric materials such a silicon nitride, silicon oxynitride and silicon dioxide. After the deposition of the deep trench liner 142, a deep trench liner etch process is used to create a deep trench liner gap 145 which provides an electrically conductive path between the subsequently deposited electrically conductive deep trench poly silicon fill 146 and the base wafer 104. After the formation of the deep trench liner gap 145, a polysilicon deposition process is used to form the electrically conductive deep trench polysilicon fill 146 on the deep trench liner 142. The electrically conductive deep trench polysilicon fill 146 is p-type doped with a dopant such as boron by way of example. The electrically conductive deep trench polysilicon fill 146 and deep trench liner 142 outside of the deep trench 140 are subsequently removed by a CMP process (not specifically shown).

Referring to FIG. 1K, the remaining process steps necessary to complete the formation of the integrated deep trench 134 and the formation of the electrical component 174 (a CMOS transistor in this example) are shown. The buried capacitor array 170 or a portion of the buried capacitor array 170 may be under the electrical component 174. A well 150 is implanted to provide electrical contact to the deep trench deep well region 138 of the integrated deep trench 134, the integrated buried capacitor 172 and the buried trench capacitor array 170. A field oxide 148 is formed in a series of steps consisting of a pattern, an etch, a field oxide fill step, and CMP steps (none specifically shown). The field oxide 148 provides isolation for the electrical component 174 as well as electrical isolation for the integrated deep trench 134. The remaining components of the CMOS transistor of the example device shown in FIG. 1K consist of a gate oxide 152 on the top epitaxial silicon top surface 137, and gate electrode material 154 on the gate oxide 152 which forms the transistor gate electrode 156. The transistor includes a halo implant region 158 and a source/drain implant region 160. A sidewall 162 is formed on the lateral surfaces of the gate electrode 157. A metal silicide 159 may be formed on exposed silicon surfaces on the top epitaxial silicon top surface 137 of the silicon. A pre-metal dielectric (PMD) 164 is formed on over the top epitaxial silicon top surface 137 of the microelectronic device 100. Contacts 165 and metallization 166 are formed to provide electrical contact between a first buried trench capacitor terminal 176 of the integrated buried capacitor 172, a second buried trench capacitor terminal 178 of the integrated buried capacitor 172 and the electrical component 174.

The first buried trench capacitor terminal 176 provides electrical connection through the integrated deep trench 134 through the substrate 102 to the electrically conductive buried capacitor trench-fill material 126. The second buried trench capacitor terminal 178 provides electrical connection through a well 150 and the deep trench deep well region 138 to the buried trench capacitor buried capacitor deep well 108.

The microelectronic device 100 can be viewed as consisting of three distinct regions. The first is the buried trench capacitor array 170. The second region is the integrated buried capacitor 172 which includes the buried trench capacitor array 170 and the integrated deep trench 134. The third region is the electrical component 174, a CMOS transistor in this example.

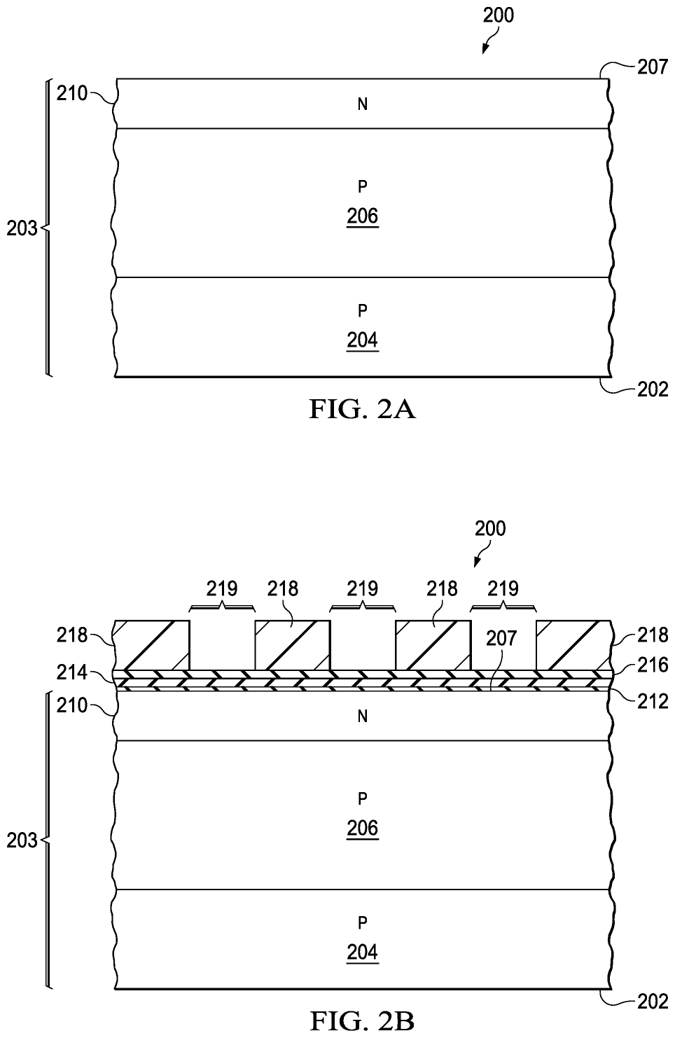

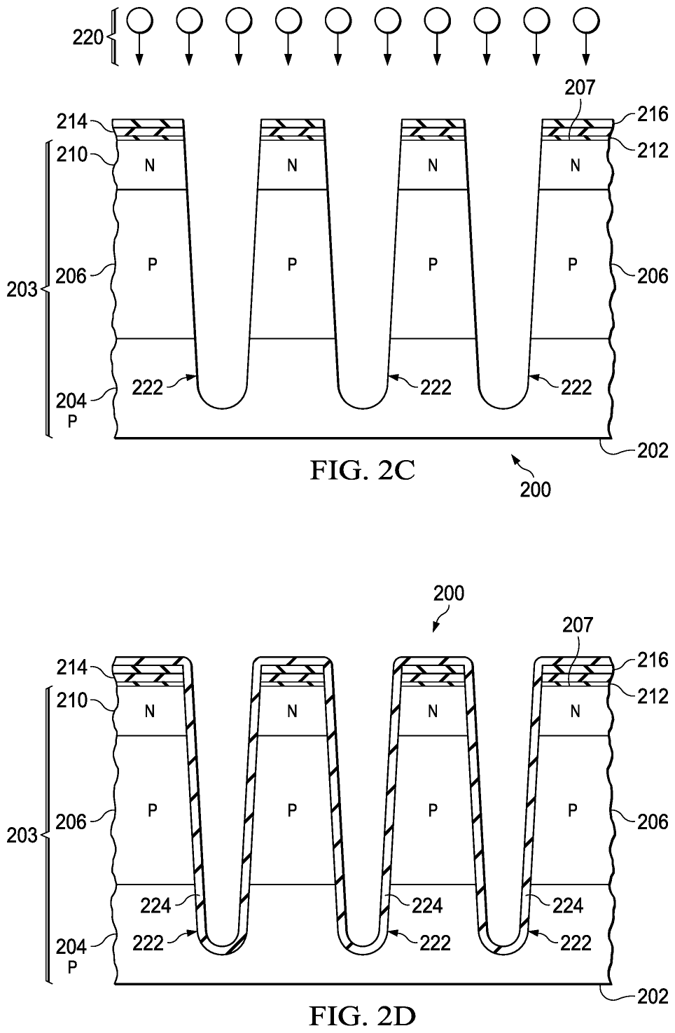

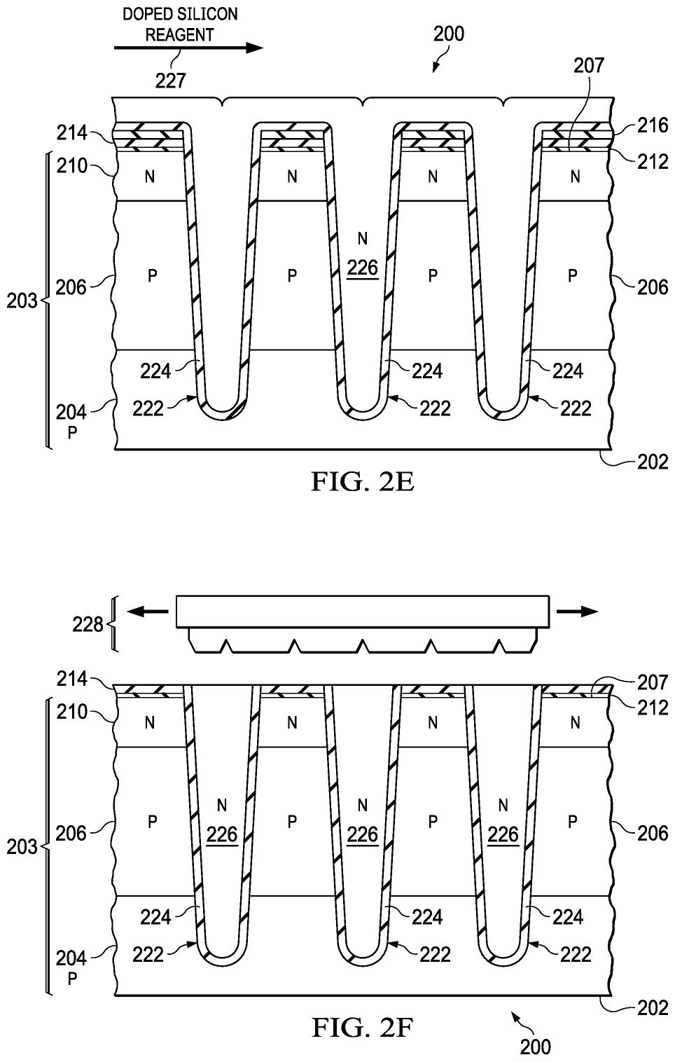

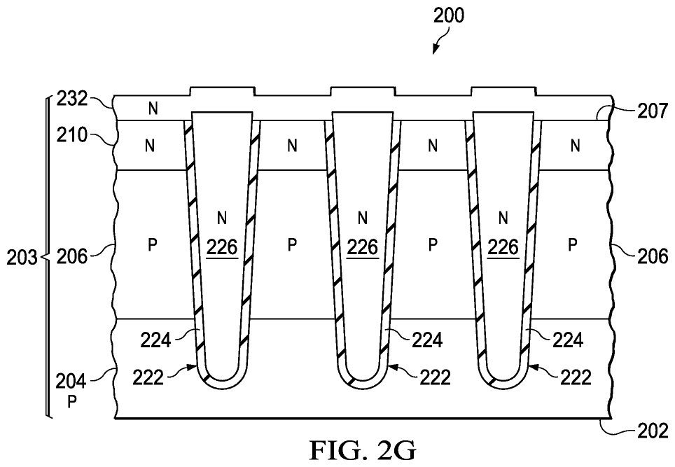

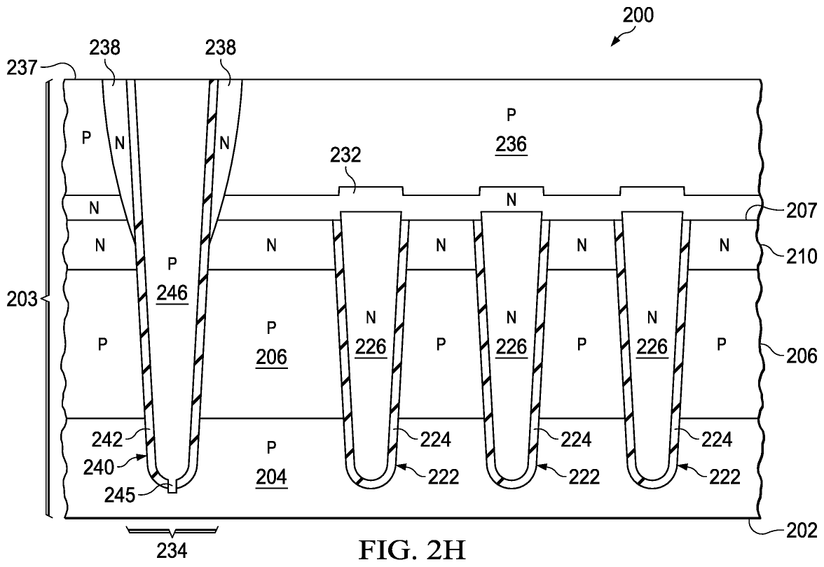

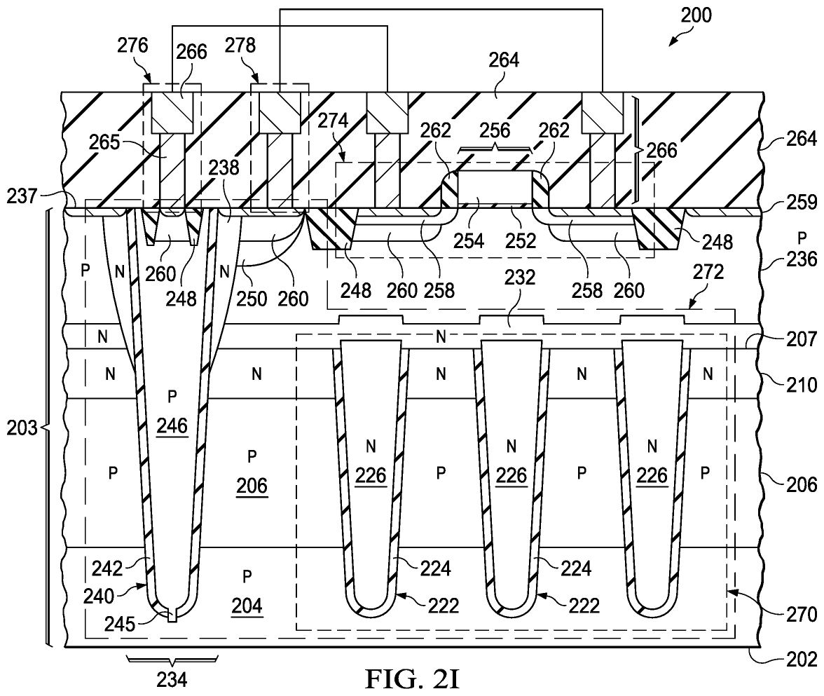

FIG. 2A through FIG. 2I are cross sections of an example microelectronic device 200 depicted in successive stages of an example method of formation containing a buried trench capacitor array 270 as part of an integrated buried capacitor 272, the integrated buried capacitor 272 providing a capacitance source to an electrical component 274.

Referring to FIG. 2A, the microelectronic device 200 is formed in and on a substrate 202 that has a semiconductor material 203 referred to herein as the silicon 203. In this example, the substrate 202 may include a base wafer 204, such as a silicon wafer. In an alternate version of this example, the substrate 202 may include a dielectric material, such as silicon dioxide or sapphire, to provide a silicon-on-insulator substrate. The base wafer 204 may have a first conductivity type, which may be p-type in this example. A first epitaxial layer 206 is formed on the base wafer 204. The first epitaxial layer 206 includes primarily silicon, and may consist essentially of silicon and dopants, such as boron. The first epitaxial layer 206 has a first epitaxial top surface 207. In this example, the first epitaxial layer 206 may have the first conductivity type, that is, p-type. The first epitaxial layer 206 may be 5 microns to 15 microns thick, by way of example.

A buried layer 210 may be formed in the first epitaxial layer 206. The buried layer 210 has a second conductivity type, opposite from the first conductivity type. In this example, the second conductivity type is n-type. The buried layer 210 may be formed by implanting dopants of the second conductivity type, such as phosphorus, arsenic, or antimony, into first epitaxial layer 206. The buried layer 210 may have an average dopant density greater than twice an average dopant density of the first epitaxial layer 206. The base wafer 204 may be annealed after the buried layer implant.

Referring to FIG. 2B, a pad oxide layer 212 may be formed on the first epitaxial top surface 207 of the first epitaxial layer 206. The pad oxide layer 212 may include primarily silicon dioxide, may be formed by a thermal oxidation process or a thermal chemical vapor deposition (CVD) process, and may have a thickness of 50 nanometers to 200 nanometers, by way of example. A nitride cap layer 214 may be formed on the pad oxide layer 212. The nitride cap layer 214 may include primarily silicon nitride, may be formed by a low-pressure chemical vapor deposition (LPCVD) furnace process, and may have a thickness of 100 nanometers to 500 nanometers, for example. A hard mask layer 216 may be formed on the nitride cap layer 214. The hard mask layer 216 may include primarily silicon dioxide, may be formed by a plasma enhanced chemical vapor deposition (PECVD) process, and may have a thickness of 1 micron to 3 microns, depending on a depth of subsequently-formed buried capacitor trench 222, shown in FIG. 1C. The pad oxide layer 212 may provide stress relief between the first epitaxial layer 206 and a combination of the nitride cap layer 214 and the hard mask layer 216. The nitride cap layer 214 may provide a stop layer for subsequent etch and planarization processes. The hard mask layer 216 may provide a hard mask during a subsequent buried capacitor etch process 220 discussed in FIG. 1C to form the buried capacitor trench 122. Next, a buried capacitor trench mask 218 may be formed on the hard mask layer 216 with buried capacitor trench mask openings 219 which expose the hard mask layer 216 in an area for the buried capacitor trench 222. The buried capacitor trench mask 218 may include photoresist, and may optionally include anti-reflection material such as a bottom anti-reflection coat (BARC). The buried capacitor trench mask 218 may be formed by a photolithographic process.

Referring to FIG. 2C, a buried capacitor etch process 220 is performed to form the buried capacitor trench 222 in the first epitaxial layer 206. The buried capacitor etch process 220 may include multiple steps. In one implementation for example, a hard mask etch may be first performed to remove the hard mask layer 216 where exposed by the buried capacitor trench mask 218 of FIG. 1B, and a silicon etch may then be performed to remove the nitride cap layer 214, the pad oxide layer 212, and the first epitaxial layer 206 in regions that are exposed by the hard mask layer 216 to form the buried capacitor trench 222. The buried capacitor trench 222 extends from the first epitaxial top surface 207 into the first epitaxial layer 206 and may extend into the base wafer 204. During the silicon etch, the buried capacitor trench mask 218 may also be partially or completely removed, leaving the hard mask layer 216 to prevent the area outside of the buried capacitor trench 222 from being etched. FIG. 1C depicts the buried capacitor etch process 220 at completion, and the buried capacitor trench mask 218 has been removed by the subsequent buried capacitor trench etch clean-up process (not specifically shown). The organic polymers in the buried capacitor trench mask 218 may be removed using an oxygen plasma, followed by a series of wet etch processes, including an aqueous mixture of sulfuric acid and hydrogen peroxide, an aqueous mixture of ammonium hydroxide and hydrogen peroxide, and an aqueous mixture of hydrochloric acid and hydrogen peroxide.

Referring to FIG. 2D, a trench liner dielectric layer 224 is formed in the buried capacitor trench 222, contacting the first epitaxial layer 206 and the base wafer 204. The trench liner dielectric layer 224 may extend over the hard mask layer 216, the nitride cap layer 214, and the pad oxide layer 212. The trench liner dielectric layer 224 may include a single layer of a silicon-nitrogen compound or a silicon dioxide compound or may include multiple layers of silicon-nitrogen compounds, silicon dioxide compounds, or other dielectric materials.

Referring to FIG. 2E, an electrically conductive buried capacitor trench-fill material 226 is formed in the buried capacitor trench 222 on the trench liner dielectric layer 224. The electrically conductive buried capacitor trench-fill material 226 includes primarily silicon, and may be implemented as polycrystalline silicon, commonly referred to as polysilicon. Alternatively, the electrically conductive buried capacitor trench-fill material 226 may be implemented as amorphous silicon, or semi-amorphous silicon. The electrically conductive buried capacitor trench-fill material 226 may have the second conductivity type, n-type in this example. The electrically conductive buried capacitor trench-fill material 226 may have an average concentration of dopants of 5×10¹⁸ cm⁻³ and 1×10²⁰ cm⁻³, to provide a low equivalent resistance for the buried trench capacitor array 270. The electrically conductive buried capacitor trench-fill material 226 may be formed by thermal decomposition of a silicon-containing reagent gas that includes a doped polysilicon reagent 227. The electrically conductive buried capacitor trench-fill material 226 fills the buried capacitor trench 222 and may extend outside of the buried capacitor trench 222.

Referring to FIG. 2F, the electrically conductive buried capacitor trench-fill material 226 and the trench liner dielectric layer 224 are removed from outside of the buried capacitor trench 222. The electrically conductive buried capacitor trench-fill material 226 and the trench liner dielectric layer 224 may be removed by a planarization process, such as a chemical mechanical polish (CMP) process 228, as indicated in FIG. 1F. Alternatively, the electrically conductive buried capacitor trench-fill material 226 and the trench liner dielectric layer 224 may be removed by an etch back process. The process of removing the electrically conductive buried capacitor trench-fill material 226 and the trench liner dielectric layer 224 outside of the buried capacitor trench 222 leaves the electrically conductive buried capacitor trench-fill material 226 on the trench liner dielectric layer 224 in the buried capacitor trench 222. The process of removing the electrically conductive buried capacitor trench-fill material 226 and the trench liner dielectric layer 224 may leave the nitride cap layer 214 and the pad oxide layer 212 on the top surface 207 of the first epitaxial layer 206. The nitride cap layer 214 may provide a stop layer for the CMP process 228 or the etch back process. The nitride cap layer 214 and the pad oxide layer 212 are then removed (not specifically shown). The nitride cap layer 214 may be removed by a wet etch process using an aqueous solution of phosphoric acid at 140° C. to 170° C. The pad oxide layer 212 may be removed by a wet etch process using an aqueous solution of buffered hydrofluoric acid.

Referring to FIG. 2G, a n-type epitaxial silicon capping layer 232 is deposited over the first epitaxial top surface 207 and is in electrical contact with the electrically conductive buried capacitor trench-fill material 226. The n-type epitaxial silicon capping layer 232 may be 1 micron to 3 microns by way of example. The n-type epitaxial silicon capping layer 232 may contain n-type dopants such as arsenic or phosphorus at a concentration of 1×10¹⁵ atoms/cm³ to 1×10¹⁶ atoms/cm³.

Referring to FIG. 2H, a top epitaxial silicon 236 layer with p-type doping and an integrated deep trench 234 are formed. The top epitaxial silicon 136 layer may contain p-type dopants such as boron at a concentration of 1×10¹⁵ atoms/cm³ to 1×10¹⁶ atoms/cm³ by way of example. The top epitaxial silicon 236 layer has a top epitaxial silicon top surface 237. The thickness of the top epitaxial silicon 236 layer may be between 5 and 15 microns by way of example. The integrated deep trench 234 makes an electrical connection from the top epitaxial silicon top surface 237 of the microelectronic device to the base wafer 204. The formation of the integrated deep trench 234 begins with a pattern and implant steps to form a deep trench deep n-type well 238 followed by a pattern and etch step to define a deep trench 240.

After the formation of the deep trench 240, a deep trench liner 242 is deposited. The deep trench liner 242 is a dielectric layer. The deep trench liner 242 may be 50 A to 300 A by way of example. The deep trench liner 242 may be a single layer or multiple layers of dielectric materials such a silicon nitride, silicon oxynitride and silicon dioxide. After the deposition of the deep trench liner 242, a deep trench liner etch process is used to create a deep trench liner gap 245 which provides an electrically conductive path between the subsequently deposited electrically conductive deep trench polysilicon fill 246 and the base wafer 204. After the deep trench liner gap 245 formation, a polysilicon deposition process is used to form the electrically conductive deep trench polysilicon fill 246 on the deep trench liner 242. The electrically conductive deep trench polysilicon fill 246 is n-type doped with a dopant such as phosphorus by way of example. The electrically conductive deep trench polysilicon fill 246 and deep trench liner 242 outside of the deep trench 240 are subsequently removed by a CMP process.

Referring to FIG. 2I, the remaining process steps necessary to complete the formation of the integrated deep trench 234 and the formation of the electrical component 274 (a CMOS transistor in this example) are shown. A well 250 is implanted to provide electrical contact to the deep n-type implant 238 of the integrated deep trench 234 to the integrated buried capacitor 272 and the buried trench capacitor array 270. A field oxide 248 is formed in a series of steps consisting of a pattern, an etch, a field oxide fill step and CMP steps. The field oxide 248 provides isolation for the electrical component 274 as well as electrical isolation for the integrated deep trench 234. The remaining components of the electrical component 274 of the example device shown in FIG. 2I consist of a gate oxide 252 on the top epitaxial silicon top surface 237 and a gate electrode material 254 such as polysilicon on the gate oxide 252 which form the transistor gate electrode 256. The electrical component 274 includes a halo implant region 258 and a source/drain implant region 260. A sidewall 262 is formed on the lateral surfaces of the transistor gate electrode 256. A metal silicide 259 may be formed on exposed silicon surfaces on the top epitaxial silicon top surface 237 of the silicon. A pre-metal dielectric (PMD) 264 is formed on over the top epitaxial silicon top surface 237 of the microelectronic device 200. Contacts 265 and metallization 266 are formed to provide electrical contact between the first buried trench capacitor terminal 276 of the integrated buried capacitor 272, the second buried trench capacitor terminal 278 of the integrated buried capacitor 272 and the electrical component 274.

The first buried trench capacitor terminal 276 of the integrated buried capacitor 272 provides electrical connection through the integrated deep trench 234 and the substrate 202 to the base wafer 204. The second buried trench capacitor terminal 278 of the integrated buried capacitor 272 provides electrical connection through the well 250 and n-type epitaxial silicon capping layer 232 to the electrically conductive buried capacitor trench-fill material 226.

The microelectronic device 200 can be viewed as consisting of three distinct regions. The first is the buried trench capacitor array 270. The second region is the integrated buried capacitor 272 which includes the buried trench capacitor array 270 and the integrated deep trench 234. The third region is the electrical component 274, a CMOS transistor in this example, but may be a laterally diffused MOS transistor (LDMOS) transistor, a drain extended metal oxide semiconductor (DEMOS) transistor, a bipolar junction transistor, a junction field effect transistor, a gated bipolar, a gated unipolar semiconductor device, an insulated gate bipolar transistor (IGBT), a silicon controlled rectifier (SCR), a metal oxide semiconductor (MOS)-triggered SCR, a MOS-controlled thyristor, a gated diode, a resistor, an amplifier, and a Schottky diode by way of example.

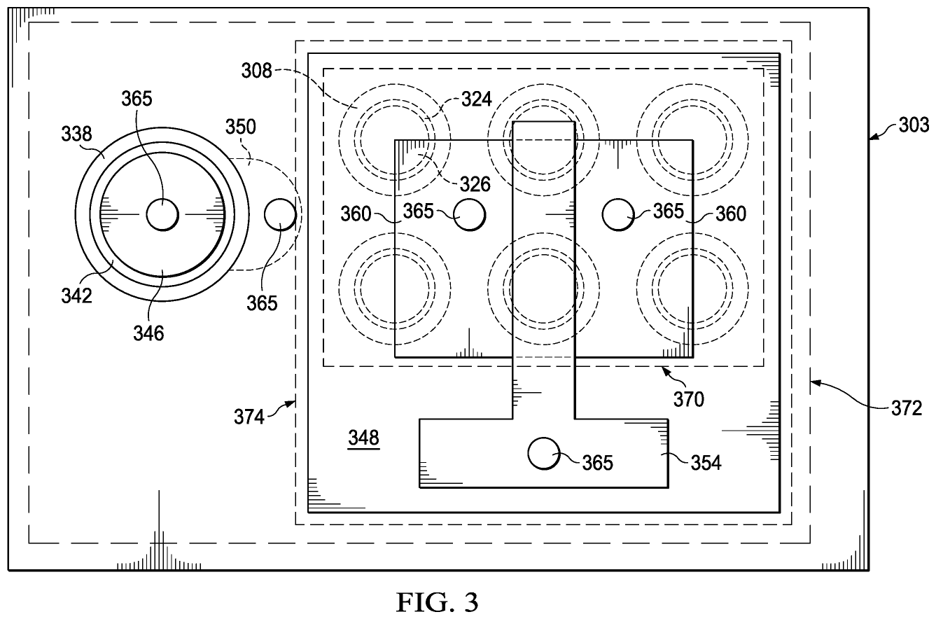

Referring to FIG. 3, a top-down view highlighting the key features of FIG. 1K including a buried trench capacitor array 370, an integrated buried capacitor 372 and the electrical component 374 (a CMOS transistor in this example) are shown. All of the components are in the silicon 303. The trench-fill material 326, trench liner dielectric layer 324, and the buried capacitor deep well 308, form the buried trench capacitor array 370. The buried trench capacitor array 370 is under the electrical component 374. It is advantageous to place the buried trench capacitor array 370 under the electrical component 374 for area savings and to lower the electromagnetic interference (EMI) of the microelectronic device 300. Contacts 365 are shown, but the metallization is not shown for clarity. The components of the deep trench consist of the electrically conductive deep trench polysilicon fill 346, deep trench liner 342, and the deep trench deep well 338. A well 350 is in contact with the dee well 338 to provide an electrical path to buried trench capacitor array 370. The electrical component 374 (a CMOS transistor in this example), consist of the gate electrode material 354, source and drain regions 360, surrounded by an isolation region 348.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above-described embodiments. Rather, the scope of the disclosure should be defined in accordance with the following claims and their equivalents.

What is claimed is:

1. A microelectronic device comprising:
a base wafer having a layer of silicon;
a first epitaxial layer on the base wafer having a first epitaxial layer top surface;
a buried trench capacitor extending into the first epitaxial layer; and
a second epitaxial layer over the buried trench capacitor.

2. The microelectronic device of claim 1, wherein the buried trench capacitor comprises:
a buried trench capacitor array below the second epitaxial layer, including;
a buried capacitor trench in the first epitaxial layer and in the base wafer;
a buried capacitor deep well of a first conductivity type around the buried capacitor trench;
a trench liner dielectric in the buried capacitor trench;
a trench liner gap through the trench liner dielectric to the base wafer;
a trench-fill material on the trench liner dielectric in the buried capacitor trench, the trench-fill material being electrically conductive and having a second conductivity type opposite the first conductivity type; and
a buried trench capacitor silicon dioxide cap on the trench-fill material.

3. The microelectronic device of claim 2, wherein the buried trench capacitor further comprises:
a first buried trench capacitor terminal contacting the base wafer; and
a second buried trench capacitor terminal contacting the buried capacitor deep well around the buried capacitor trench.

4. The microelectronic device of claim 2 further including an epitaxial silicon capping layer of the second conductivity type on the buried trench capacitor silicon dioxide cap.

5. The microelectronic device of claim 2 further including a buried layer of the first conductivity type in the first epitaxial layer.

6. The microelectronic device of claim 2 further including an electrical component at a surface of the second epitaxial layer and extending at least partially over the buried trench capacitor array.

7. The microelectronic device of claim 2 further including an integrated deep trench containing a deep trench liner gap which provides an electrical connection between a first buried trench capacitor terminal and the trench-fill material of the buried trench capacitor array.

8. The microelectronic device of claim 2 further including a deep trench n-type deep well provides electrical connection between a second buried trench capacitor terminal and the buried capacitor deep well of the buried trench capacitor array.

9. A microelectronic device, including a buried trench capacitor comprising:
a base wafer having a layer of silicon;
a first epitaxial layer on the base wafer having a first epitaxial layer top surface; and
a buried trench capacitor having:
an array of buried trench capacitor cells in the first epitaxial layer, each buried trench capacitor cell including;
a buried capacitor trench in the first epitaxial layer and in the base wafer;
a buried capacitor trench liner dielectric in the buried capacitor trench;
a n-type electrically conductive buried capacitor trench-fill material on the buried capacitor trench liner dielectric;
a n-type epitaxial silicon capping layer over the buried trench capacitor;
a first buried trench capacitor terminal contacting the base wafer;
a second buried trench capacitor terminal contacting the n-type epitaxial silicon capping layer; and
a second p-type epitaxial layer on the n-type epitaxial silicon capping layer.

10. The microelectronic device of claim 9 further including an electrical component extending at least partially over the array of buried trench capacitor cells.

11. The microelectronic device of claim 9 further including an integrated deep trench containing a deep trench liner gap which provides an electrical connection between a first buried trench capacitor terminal and the n-type electrically conductive buried capacitor trench-fill material of the buried trench capacitor.

12. The microelectronic device of claim 9 further including a deep trench n-type deep well which provides electrical connection between a second buried trench capacitor terminal and the n-type epitaxial silicon capping layer.

13. A method of forming a microelectronic device including:
forming a first epitaxial layer on a base wafer, the first epitaxial layer having a top surface;
forming a buried trench capacitor extending into the first epitaxial layer; and
a second epitaxial layer over the buried trench capacitor.

14. The method of claim 13 wherein the buried trench capacitor includes;
forming a buried trench capacitor array below the second epitaxial layer, including;
forming a buried capacitor trench in the first epitaxial layer and in the base wafer;
forming a deep well of a first conductivity type around the buried capacitor trench;
forming a trench liner dielectric in the buried capacitor trench;
forming a trench liner gap through the trench liner dielectric to the base wafer;
forming a trench-fill material on the trench liner dielectric in the buried capacitor trench, the trench-fill material being electrically conductive and having a second conductivity type; and
forming a buried trench capacitor silicon dioxide cap on the trench-fill material.

15. The method of claim 14 wherein the buried trench capacitor includes;
forming a first buried trench capacitor terminal contacting the base wafer; and
forming a second buried trench capacitor terminal contacting the deep well around the buried trench capacitor.

16. The method of claim 13 wherein a p-type epitaxial silicon capping layer is formed on the buried trench capacitor silicon dioxide cap.

17. The method of claim 13 wherein an n-type buried layer is formed in the first epitaxial layer.

18. The method of claim 13 wherein an electrical component of the microelectronic device is electrically in contact in parallel with the buried trench capacitor array.

19. The method of claim 13 wherein an integrated deep trench containing a deep trench liner gap which provides an electrical connection between a first buried trench capacitor terminal and the trench-fill material of the buried trench capacitor array.

20. The method of claim 13 wherein a deep trench n-type deep well provides electrical connection between a second buried trench capacitor terminal and the deep well of the buried trench capacitor array.

21. A method of forming a microelectronic device with a buried capacitor including:
forming a first epitaxial layer on a base wafer of a substrate;
forming a buried trench capacitor array including;
forming a buried capacitor trench in the first epitaxial layer and in the base wafer;
forming a buried capacitor trench liner dielectric on the buried capacitor trench;
forming a n-type electrically conductive buried capacitor trench-fill material on the buried capacitor trench liner dielectric; and
forming a second p-type epitaxial layer on the buried trench capacitor array;
forming a first buried trench capacitor terminal contacting the base wafer; and
forming a second buried trench capacitor terminal contacting a deep well around the buried capacitor trench.

22. The method of claim 21 wherein a deep trench n-type deep well provides electrical connection between a second buried trench capacitor terminal and the first epitaxial layer of the buried trench capacitor array.
